(19) United States
(12) Patent Application Publication
(10) Pub. No.: US 2017/0338391 A1
(43) Pub. Date: Nov. 23, 2017

(54) HEAT-SINK PATCH LED LUMINESCENT TUBE

(71) Applicant: Zhenliang LIU, Henan (CN)

(72) Inventor: Zhenliang LIU, Henan (CN)

(21) Appl. No.: 15/526,338

(22) PCT Filed: Oct. 22, 2015
(86) PCT No.: PCT/CN2015/092588

§ 371 Date: May 12, 2017

(30) Foreign Application Priority Data
Jun. 10, 2015 (CN) 201520394581.1

(51) Int. Cl. H01L 33/64; H01L 23/00; H01L 33/48

(52) U.S. Cl. CPC H01L 33/64; H01L 33/486; H01L 24/73; H01L 2224/48247; H01L 2224/73265; H01L 2224/48091

(57) ABSTRACT

This utility model provides a type of heat-sink surface-mounted LED luminescent tube, comprising a first electrode pin used as a heat sink, and an LED chip, wherein the first electrode pin is composed of a first horizontal section electrode, a second horizontal section electrode and a protrusion heat sink, which are connected sequentially; the LED chip is mounted on the first horizontal section of the first electrode pin, a first electrode of the LED chip is connected with the first horizontal section, and a second electrode of the LED chip is connected with the third horizontal section through a conducting wire. When the actual patch is welded to this new utility model, the heat sink formed by the protrusion will penetrate a reserved copper hole in the circuit board to be connected with external metal elements, which radiates heat.

### BACKGROUND OF THE INVENTION

This utility model relates to the field of LED, in particular to a heat-sink surface-mounted LED luminescent tube.

Existing surface-mounted LED luminescent tubes have flat pins at the bottom directly welded onto the circuit board. Transmission of heat generated by the light point is always blocked by the fiber circuit board with poor heat conductivity, and the temperature increase of the light point in the heat of outdoor environments will lead to light-induced degradation and blackouts. Improving heat dissipation in surface-mounted luminescent tubes, especially mini-watt all-color series luminescent tubes, the key lies in the technology behind outdoor LED surface-mounted display screens.

### BRIEF SUMMARY OF THE INVENTION

The utility model provides a heat-sink surface-mounted LED luminescent tube, which is simple in structure, low in cost and good in heat dissipation.

In order to solve the above problem, which is an aspect of this utility model, a heat-sink surface-mounted LED luminescent tube is provided, comprising a first electrode pin used as a heat sink, a second electrode pin, a capsule, and an LED chip, wherein the first electrode pin is composed of a first horizontal section, a first bending section, a second horizontal section and a protrusion, which are connected sequentially; the second electrode pin is composed of a third horizontal section, a second bending section and a fourth horizontal section, which are connected sequentially; the capsule encloses the first and second electrode pins as the support, and the protrusion extends downwardly out of the capsule; the LED chip is mounted on the first horizontal section of the first electrode pin, a first electrode of the LED chip is connected with the first horizontal section, and a second electrode of the LED chip is connected with the third horizontal section through a lead.

Preferably, the LED chip is fixed on the first horizontal section through silver adhesive or insulation paste.

Preferably, the capsule comprises of a cylindrical or frustoconical upper portion and a square lower portion.

Preferably, the first horizontal section, the first bending section, the third horizontal section, and the second bending section are all arranged in the lower portion, and the second horizontal section and the fourth horizontal section are flush welded with the bottom surface of the lower portion.

Preferably, the LED chip is arranged in the mounting cavity of the upper portion.

Preferably, the mounting cavity is filled with sealant.

Preferably, the mounting cavity is either cylindrical or frustoconical.

Preferably, the first electrode pin and the second electrode pin are arranged pairwise, the heat-sink surface-mounted LED luminescent tube comprises pairs of first and second electrode pins. There are several LED chips, and each first electrode pin is provided with one LED chip.

Preferably, there are 3 LED chips, which are red, green and blue respectively.

Heat generated by the LED chip transmits to the second horizontal section by way of the first horizontal section of the first electrode pin. In surface mounting and welding, the heat sink formed by the protrusion will penetrate a reserved copper hole in a circuit board, and the heat of the chip, due to its high thermal conductivity, is directly transmitted from the light point to the other side of the circuit board, and then to the external environment to realize the heat dissipation of the “heat sink”. The heat-sink surface-mounted LED luminescent tube has the advantages of simple structure, good heat dissipation, and low cost.

### BRIEF DESCRIPTION OF THE DRAWINGS

FIG. 1 shows the structural diagram of the utility model.

### NOTATION FOR THE FIGURE

1. First horizontal section, 2. first bending section, 3. second horizontal section, 4. third horizontal section, 5. second bending section, 6. fourth horizontal section, 7. capsule, 8. LED chip, 9. conducting wire, 10. protrusion, 11. silver adhesive, 12. upper portion, 13. lower portion, and 14. sealant.

### DETAILED DESCRIPTION OF THE INVENTION

Below is a detailed description of the utility model with reference to the accompanying drawings, but the utility model may be embodied in many different ways as defined and covered by the claims.

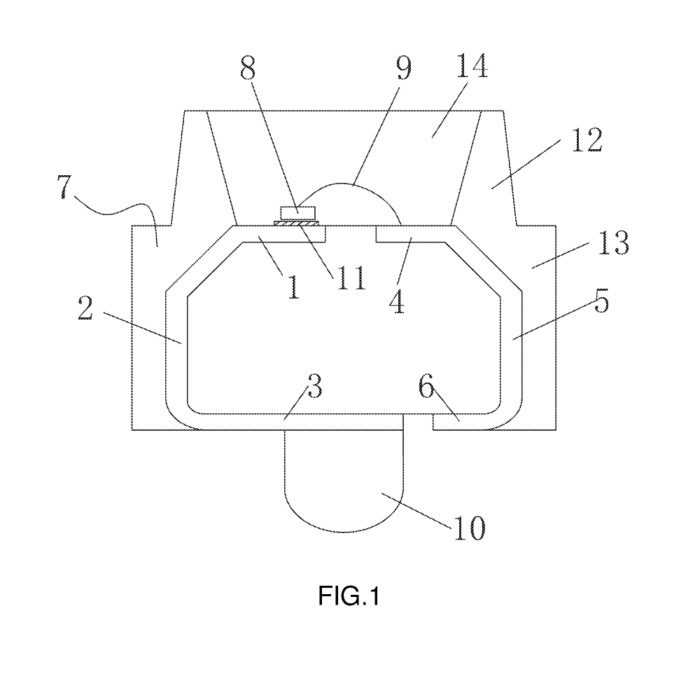

As shown in FIG. 1, the utility model provides a heat-sink surface-mounted LED luminescent tube, comprising a first electrode pin used as a heat sink, a second electrode pin, a capsule 7, and an LED chip 8, wherein the first electrode pin is composed of a first horizontal section 1, a first bending section 2, a second horizontal section 3 and a protrusion 10, which are connected sequentially; the second electrode pin is composed of a third horizontal section 4, a second bending section 5 and a fourth horizontal section 6, which are connected sequentially; the capsule encloses the first and second electrode pins as the support, and the protrusion extends downwardly out of the capsule; the LED chip 8 is mounted on the first horizontal section 1 of the first electrode pin, a first electrode of the LED chip 8 is connected with the first horizontal section 1, and a second electrode of the LED chip 8 is connected with the third horizontal section 4 through a conducting wire 9.

Among them, the first electrode pin and the second electrode pin can conduct heat and electricity at the same time. The LED chip 8 is fixed on the first electrode pin. Preferably, the first electrode pin and the second electrode pin are formed through the process of hardware punching. The second horizontal section 3 and the fourth horizontal section 6 are arranged on the same plane and form the pin.

Heat generated by the LED chip 8 transmits to the second horizontal section 3 by way of the first horizontal section 1 of the first electrode pin. In surface mounting and welding, the heat sink formed by the protrusion will penetrate a reserved copper hole in the circuit board, and the heat of the chip, due to its high thermal conductivity, is directly transmitted from the light point to the other side of the circuit board, and then to the external environment to realize the heat dissipation of the “heat sink”. The heat-sink surface-mounted LED luminescent tube has the advantages of simple structure, good heat radiation effect, and low cost.

Preferably, the protrusion 10 extends downwardly relative to the second horizontal section 3.

Preferably, the LED chip 8 is fixed in the first horizontal section 1 via silver adhesive 11 or an insulation paste. The silver adhesive 11 functions as a conductor of electricity and heat.

Preferably, the capsule 7 comprises a cylindrical or frustoconical upper portion 12 and a square lower portion 13. In light of the requirements for higher black and white contrast of the outdoor surface-mounted display screen, the external structure, with the circular upper portion and the square lower portion, can ensure that under the premise that the LED chip can emit light and be encapsulated, the circular white area of the upper portion is the minimum, while the square lower portion achieves the optimal surface-mounting flatness, stability and reliability required in the package.

Preferably, the first horizontal section 1, the first bending section 2, the third horizontal section 4 and the second bending section 5 are all arranged in the lower portion 13, and the second horizontal section 3 and the fourth horizontal section 6 are flush welded with the bottom surface of the lower portion 13. Thus, only the second horizontal section 3, the fourth horizontal section 6 and the protrusion 10 are exposed, and the excellent air-tightness and waterproof performance are thereby achieved.

Preferably, the LED chip 8 is arranged in the mounting cavity of the upper portion 12. Preferably, the mounting cavity is cylindrical or frustoconical.

Preferably, the mounting cavity is filled with sealant 14. The sealant 14 plays a role in allowing light transmission and protecting the LED chip 8.

Preferably, the first electrode pin and the second electrode pin are arranged pairwise, the heat-sink surface-mounted LED luminescent tube comprises pairs of first electrode pins and second electrode pins. There are several LED chips 8, and each first electrode pin is provided with one LED chip 8.

Preferably, there are 3 LED chips 8, which are red, green and blue respectively. In this way, the all-color LED luminescent tube can be realized. Apparently, the number of the LED chips is not limited to three, and can be more.

The above description is only a preferred embodiment of the utility model and is not intended to limit the utility model. The utility model can be varied and modified by any skilled professional. Any modifications, adjustments, or improvements etc. within the spirit and principles of the utility model should be included within the scope of this utility model.

What is claimed is:

1. A type of heat-sink surface-mounted LED luminescent tube, characteristics include:
A first electrode pin used as a heat sink, composed of a first horizontal section (1), a first bending section (2), a second horizontal section (3), and a protrusion (10), which are sequentially connected;
A second electrode pin composed of a third horizontal section (4), a second bending section (5), and a fourth horizontal section (6), which are sequentially connected;
A capsule (7) enclosing the first electrode pin and the second electrode pin as the support, and the protrusion (10) which extends downwardly out of the capsule (7);
An LED chip (8) mounted on the first horizontal section (1) of the first electrode pin, a first electrode of the LED chip (8) is connected with the first horizontal section (1), and a second electrode of the LED chip (8) is connected with the third horizontal section (4) through a conducting wire (9).

2. The heat-sink surface-mounted LED luminescent tube according to claim 1, wherein the LED chip (8) is fixed on the first horizontal section by (1) a silver adhesive (11) or an insulation paste.

3. The heat-sink surface-mounted LED luminescent tube according to claim 1, wherein the capsule (7) comprises a cylindrical or frustoconical upper portion (12) and a square lower portion (13).

4. The heat-sink surface-mounted LED luminescent tube according to claim 3, wherein the first horizontal section (1), the first bending section (2), the third horizontal section (4), and the second bending section (5) are all arranged in the lower portion (13), and the second horizontal section (3) and the fourth horizontal section (6) are flush welded to the bottom surface of the lower portion (13).

5. The heat-sink surface-mounted LED luminescent tube according to claim 3, wherein the LED chip (8) is arranged in a mounting cavity of the described upper portion (12).

6. The heat-sink surface-mounted LED luminescent tube according to claim 5, wherein the mounting cavity is filled with sealant (14).

7. The heat-sink surface-mounted LED luminescent tube according to claim 5, wherein the mounting cavity is either cylindrical or frustoconical.

8. The heat-sink surface-mounted LED luminescent tube according to claim 1, wherein the first electrode pin and the second electrode pin are arranged pairwise, the heat-sink surface-mounted LED luminescent tube comprises pairs of first and second electrode pins. There are several LED chips (8), and each first electrode pin is provided with one LED chip (8).

9. The heat-sink surface-mounted LED luminescent tube according to claim 8, wherein there are 3 LED chips (8), which are red, green and blue respectively.
